(19) United States
(12) Patent Application Publication
(10) Pub. No.: US 2008/0014715 A1
(43) Pub. Date: Jan. 17, 2008

(54) DEVICE AND METHOD FOR THE PROCESSING OF WAFERS

(75) Inventors: Hans Leitner, Landskron (AT); Josef Schwaiger, Teugn (DE); Werner Kroeninger, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 11/777,699

(22) Filed: Jul. 13, 2007

(30) Foreign Application Priority Data
Jul. 13, 2006 (DE) 10 2006 032 488.9

(51) Int. Cl. H01L 21/30; H01L 21/46

(52) U.S. Cl. 438/458

(57) ABSTRACT

A device and a method for the processing of wafers is disclosed. One embodiment provides a method and a device in which a system wafer is bonded to a carrier work piece by using a bonding substance so as to increase the stability of the system wafer. After processing of the system wafer, the bonding effect of the bonding substance is cancelled. The system wafer can easily be detached from the carrier work piece without cutting out the carrier work piece, so that the dust exposure and the mechanical stress of the system wafer which occurs during the cutting out of the carrier work piece is avoided.

### CROSS-REFERENCE TO RELATED APPLICATIONS

This Utility patent application claims priority to German Patent Application No. DE 10 2006 032 488.9 filed on Jul. 13, 2006, which is incorporated herein by reference.

### BACKGROUND

The present invention relates in general to the processing of wafers, in particular for the manufacturing of semiconductor devices. The invention relates to both a method for the processing of wafers and a device for the processing of wafers for the manufacturing of semiconductor devices.

For manufacturing semiconductor devices, e.g., analog or digital integrated computing circuits, semiconductor memory devices such as e.g., functional memory devices (e.g., PLAs, PALs, etc.) and table memory devices (e.g., ROMs or RAMs, SRAMs or DRAMs), thin discs consisting of monocrystalline silicon are used, which are referred to as “wafers” in technical language.

In the course of the manufacturing process, the wafers are subject to a plurality of coating, exposure, etching, diffusion, and implantation process steps, etc. in order to structure the circuits of the devices on the wafer. After termination of the structuring processes, the devices are individualized on the wafer for further processing. To this end, the processed wafer or system wafer is, for instance, sawn apart, scratched, or broken so as to separate the devices from each other.

After the dividing or sawing apart of the wafer, the devices are individually arranged on a base body for contacting. The base body may be a lead frame of a chip package, or any substrate, e.g., for performing test series with the semiconductor device chip.

In some devices, one has been striving to keep the height of the device and thus the height of the finished chip as small as possible. To this end, the processed system wafer may be thinned, i.e. its thickness may be reduced, even prior to the individualization of the devices. This is, for instance, performed by grinding the back of the system wafer while the processed structures of the devices are arranged on the front side. In so doing, the devices structured on the system wafer are each reduced in their thickness from their back. Thus, for instance, a thickness of approx. 100 μm or less of the system wafer or of the devices structured thereon may be achieved.

In order that the system wafer to be thinned or the system wafer thinned, respectively, does not break apart, the system wafer is bonded to a carrier work piece to increase its stability. As carrier work piece, a carrier wafer may, for instance, serve which has the same dimensions and is bonded to the system wafer. To this end, the system wafer and the carrier wafer are each bonded to each other at their edges in that, for instance, the edge regions, e.g., the outermost 3 mm of the wafers, are glued together with a glue. Thus, the stiffness of the system wafer is increased and the risk of breaking during processing, in particular during the thinning of the system wafer, is reduced.

After termination of the process for thinning the system wafer and after the individualization of the devices structured on the system wafer, the carrier work piece or the carrier wafer, respectively, again has to be detached from the system wafer so as to enable the further processing of the devices. To this end, as a rule, the carrier wafer is cut out with a smaller diameter than the glued edge region (“decapping”). This way, only the glued edge region in the shape of a ring is left from the carrier wafer, which remains strongly glued with the system wafer. This remaining edge region of the carrier wafer has sufficient stiffness due to its thickness and thus gives the system wafer a stability which reduces the risk of breaking during further process steps for the processing of the system wafer.

With this process, the gluing and the subsequent cutting out of the carrier wafer entail a small surface yield. Furthermore, the process of the cutting out of the carrier wafer causes a high risk of breaking for the system wafer. The mechanical stress by the process of the circular cutting out of the system wafer may, apart from the breaking, also entail invisible impairments causing disfunctions of the devices. Further, dust is generated by the cutting out of the carrier wafer, which impedes the further processing of the system wafer and of the devices structured thereon.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A to 1F illustrate each schematic representations of a wafer stack that is processed in accordance with a method according to prior art.

FIG. 2 illustrates a schematic representation of a wafer stack that is processed in accordance with a method according to a preferred embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide a system and a method for the processing of wafers, in particular for the manufacturing of semiconductor devices, which stands out by a small risk of breaking for the wafer. Further, the present embodiments reduce the mechanical stress and the dust exposure during the processing of the wafer.

One embodiment provides a method for processing a wafer in which a system wafer is subject to a number of processes in order to structure a number of devices on the system wafer, and the system wafer is bonded to a carrier work piece so as to increase the stability of the system wafer, the method including at least the following processes:

bonding the system wafer to a carrier work piece over at least a particular region of the system wafer by using a bonding substance with bonding effect;

performing one or a plurality of intermediate processes for processing the system wafer;

heating the bonding substance, so that the bonding effect of the bonding substance is cancelled; and

separating the system wafer from the carrier work piece.

A wafer stack is consequently generated first of all in that a system wafer and a carrier wafer as a carrier work piece are bonded to one another by using a bonding substance so as to increase the stability of the system wafer and to reduce the mechanical stress on the system wafer and the risk of breaking during the manufacturing processes. Subsequently, in accordance with the present invention, the system wafer may be detached from the carrier work piece in a simple manner in that the bonding substance is heated and thus loses its bonding effect. This inventive method consequently does not require any cutting out (“decapping”) of the carrier work piece or carrier wafer, respectively, and thus avoids the mechanical stress and the dust exposure of the system wafer which otherwise occurs.

In accordance with one embodiment, the bonding substance or glue is composed on a silicone basis with respect to its chemical composition. As bonding substance, a known silicone glue “Semicosil 987” is, for instance, suitable. If the bonding substance or glue is heated and is thus subject to oxygen, the silicone will convert to silicon dioxide or sand, respectively. This way, the glue will granulate and the bonding substance will lose its bonding effect. As a result of this chemical reaction, the glue is substantially granulated and converted to sand which only has a loose coherence.

In accordance with another embodiment, the heating of the bonding substance is therefore performed by adding oxygen, so that the bonding substance gets into contact with the oxygen and oxidizes. In so doing, pure oxygen, a gas enriched with oxygen, or a gas containing oxygen, e.g., air, may be added.

The heating of the bonding substance may, for instance, be performed by using a furnace into which the entire wafer stack consisting of the system wafer and the carrier wafer is introduced. The use of a furnace for heating the bonding substance does, however, entail the disadvantage that the carrier wafer is completely heated together with the system wafer, so that the surface material of the system wafer may, for instance, be impaired. The already existing structures of the devices on the system wafer may also be damaged in that, for instance, aluminum conductor paths melt or their electrical conductivity changes. Nevertheless, the heating of the bonding substance by introducing the wafer stack in a furnace is a feasible embodiment of the present method if only those materials are present on the system wafer which are not impaired by the heating.

For heating the bonding substance, the duration and the temperature may be varied to keep the system wafer and its usable surface or the devices processed thereon, respectively, as unimpaired as possible. The wafer stack may, for instance, be subject to a temperature of 500° C. for 10 minutes or to a temperature of 500° C. for 4 minutes. It is decisive that the bonding substance reaches a temperature at which the chemical processes take place which oxidize the bonding substance and finally have it granulate. It has turned out particularly advantageous if the bonding substance is heated to a temperature in the range of 400° C. to 500° C.

The devices structured on the system wafer should, if possible, not be subject to the heating of the edge region since otherwise e.g., contact points of the devices may oxidize or the electrical properties of the metals in the conductor paths of the devices may be impaired unfavorably. It is therefore of advantage if not the entire system wafer including its usable surface and the devices available thereon is heated, but only those regions in which the system wafer is bonded to the carrier work piece. This can be done by using a laser.

In accordance with another embodiment, the heating of the bonding substance is performed by using a laser. The heating of the bonding substance may, however, also be performed by using another suitable heat radiation source that enables a specific heating of particular regions of the system wafer and of the carrier wafer and/or of the glue or the bonding substance.

The heating of the bonding substance between the system wafer and the carrier work piece by using the laser and/or the heat radiation source is in one embodiment performed by using direct irradiation of the bonding substance from the side into the gap between the system wafer and the carrier work piece. The heating of the bonding substance may also be performed by heating the system wafer and/or the carrier work piece substantially in those regions of the system wafer and/or the carrier work piece via which the system wafer and the carrier work piece are bonded to each other.

In particular when using a heat radiation source does the heating of the bonding substance take place in one embodiment by using a mask allowing for an irradiation by the beams of the heat radiation source or the laser substantially only in those regions of the system wafer and/or the carrier work piece or carrier wafer via which the system wafer and the carrier work piece are bonded to each other, so that a heating of the system wafer and/or of the carrier work piece substantially takes place only in those regions in which bonding substance is available, and the remaining regions are not heated, if possible.

The heating of the bonding substance and/or the bonded regions, in particular the edge region of the system wafer and/or the carrier work piece or the carrier wafer by using irradiation by the laser or the heat radiation source may be performed simultaneously or successively by continuous or step-wise modification of the irradiated areas.

Thus, for instance, the laser may continuously or step by step “drive round” the edge region of the system wafer and/or of the carrier work piece or the carrier wafer. The time required by the laser for passing over the edge region of the system wafer and/or of the carrier work piece or the carrier wafer may, for instance, be approx. 1 minute or ½ minute. Here, two proceedings are possible: On the one hand, the heating of the bonding substance or of a bonded region on the system wafer and/or the carrier wafer may be performed by the irradiation by using a laser until the desired chemical reactions have been finished and the bonding substance has lost its bonding effect.

The edge region of the wafer stack may be “driven round” or passed over by the laser until the edge region has reached a sufficient temperature and has maintained it over a sufficient period, so that the bonding substance has lost its bonding effect by the above-described chemical reactions. In so doing, the laser may circle the edge region of the wafer stack approximately 10 times per second, and this until the required temperature has been reached in the edge region for a sufficient time. When selecting the suitable proceeding, care has to be taken at any rate that the heat spreads as little as possible from the edge region of the system wafer and/or the carrier work piece or the carrier wafer into the usable surface of the system wafer so as to maintain the quality of the device structures processed on the usable surface of the system wafer.

The system wafer and the carrier work piece or the carrier wafer are bonded radially to each other in one embodiment in the edge region of the system wafer. In some applications it is necessary that the bonding between the system wafer and the carrier wafer is tight, i.e. a closed circle of bonding substance or glue has to exist between the system wafer and the carrier wafer. The active system wafer is then continuously glued with the carrier wafer over the respective edge region.

However, other applications are also conceivable in which such a tightness of the bonding between the system wafer and the carrier work piece or the carrier wafer may be dispensed with. In such cases, the system wafer and the carrier work piece or the carrier wafer may be bonded to each other in several separate zones. Alternatively, the system wafer and the carrier work piece or the carrier wafer may also be bonded at points only.

In the case of a bonding or gluing of the system wafer with the carrier work piece or the carrier wafer at points, or a bonding by separate zones, the heating of the bonding substance may also be restricted to exactly these bonded points or zones, without the entire edge region having to be heated. This way, an impairment of the devices processed on the usable surface of the system wafer can be further reduced.

The performing of one or several intermediate processes for the processing of the system wafer may include the thinning of the system wafer. As has already been described above, such thinning of the system wafer is, for instance, performed if particularly thin devices with a height of approx. 100 μm or less, e.g., for the use in chip cards, are to be generated.

A further embodiment provides a device for processing a wafer, wherein a system wafer is subject to a number of processes in order to structure a number of devices on the system wafer, and the system wafers bonded to a carrier work piece by using a bonding substance to increase the stability of the system wafer. The device includes a mechanism for heating the bonding substance such that the bonding effect of the bonding substance is cancelled and the system wafer can be detached again from the carrier work piece.

On principle, in accordance with one embodiment, there is provided a device for processing wafers in particular for the manufacturing of semiconductor devices, which is configured to heat the bonding region between the system wafer and the carrier wafer, in particular the edge region of the system wafer and/or the carrier wafer or the bonding substance directly for a particular period to a particular temperature so as to cancel the bonding effect of the bonding substance.

This takes place under oxygen atmosphere, wherein either pure oxygen, a gas enriched with oxygen, or common air is supplied. The more oxygen the gas supplied contains, the quicker will the chemical reactions proceed, by which the bonding substance or glue on silicone basis oxidizes and converts to silicon dioxide, as described above. According to another embodiment, the device includes mechanism that supply oxygen during the heating of the bonding substance, so that the bonding substance gets into contact with the oxygen and the above-described chemical processes may take place which result in the oxidation and in the granulation of a silicone-containing bonding substance or glue, respectively.

For this purpose, the device may include a furnace in which the wafer stack including the system wafer and the carrier work piece or the carrier wafer is introduced for heating so as to heat the bonding substance. The device may include a heat radiation source by which the bonded regions of the system wafer and/or the carrier work piece or the carrier wafer can be heated.

In accordance with another embodiment, the device is configured to heat the bonding substance by heating the system wafer and/or the carrier work piece or carrier wafer substantially in those regions via which the system wafer and the carrier work piece are bonded by the bonding substance. This way, the heating of the system wafer and/or the carrier work piece is restricted to those regions in which the bonding substance or glue, respectively, is present.

In one embodiment, the concentration of the heating to the regions in which the bonding substance is present is performed by using a laser that is configured such that the bonding substance can directly or by irradiation of the bonded regions, in particular the edge region of the system wafer and/or the carrier work piece, be heated with laser light. This way, the light beam of the laser passes over a circle at the edge of the system wafer. To this end, the beam of the laser is preferably adjusted to a width of 2 to 3 mm.

In accordance with another embodiment, the device includes a laser that is configured such that the bonding substance can be heated by direct irradiation with laser light into the gap between the system wafer and the carrier work piece. The radiation mechanism, the radiation duration, and/or the radiation performance of the heat radiation source or of the laser is controllable to be able to adjust the heating of the system wafer, the carrier wafer and the heating of the bonding substance exactly.

The device is configured to heat the wafer stack and thus the bonding substance to a temperature in the range between 400° C. and 500° C., so that the above-described reactions may take place in the bonding substance. In accordance with one embodiment, the laser is configured such that only the edge region of the wafer stack can be heated to approx. 500° C. by the laser light. If the system wafer is bonded to the carrier work piece or the carrier wafer only in points or by separate zones, the laser is in one embodiment controlled such that the heating of the wafer stack is restricted to exactly these bonded points or zones, without the entire edge region of the wafer stack having to be heated.

In accordance with another embodiment, the heat radiation source or the laser is configured such that the heating of the bonding substance and/or the bonded regions of the system wafer and/or the carrier work piece is performed by using irradiation by the heat radiation source or the laser simultaneously or successively by continuous or step-wise modification of the irradiated faces. To this end, the radiation duration of the laser can be operated continuously or in pulse operation.

The device according to the invention may further include a mask that allows for an irradiation by the beams of the heat radiation source or of the laser substantially only of those regions of the system wafer and/or the carrier work piece via which the system wafer and the carrier work piece are bonded to each other, so that a heating of the system wafer or the carrier work piece substantially only takes place in those regions in which bonding substance is present.

It is to be understood that the features of the various exemplary embodiments described herein may be combined with each other, unless specifically noted otherwise.

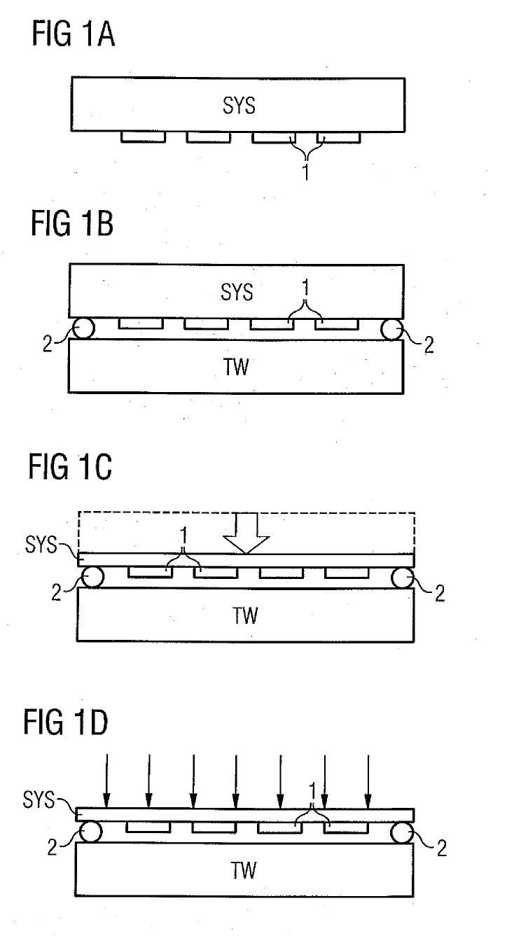

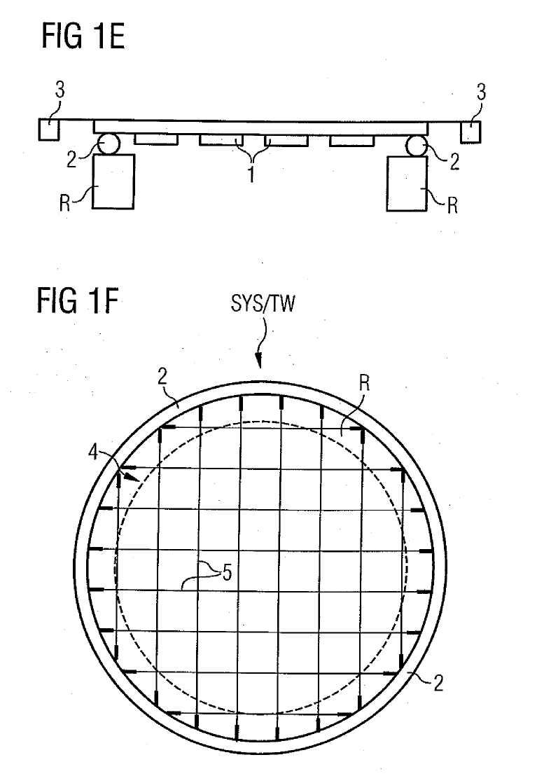

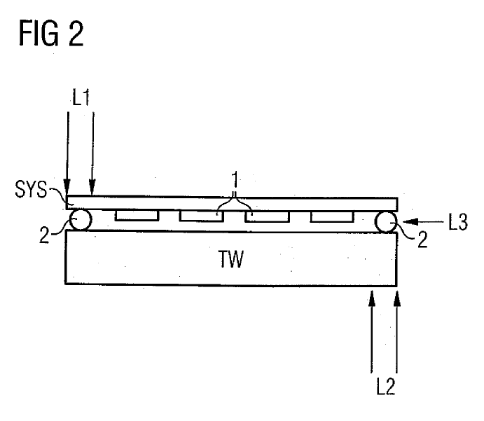

FIGS. 1A to 1F each illustrate schematic representations of a wafer stack that is processed in accordance with a method according to prior art, wherein FIGS. 1A to 1E each illustrate a schematic cross-section of the wafer stack, and FIG. 1F illustrates a schematic top view of the wafer stack. The method illustrated in FIGS. 1A to 1F serves the manufacturing of particularly thin devices 1 approximately with a height of approx. 100 μm or less, which are, for instance, suited to be used in chip cards. The method illustrated in FIGS. 1A to 1D also constitutes the first process of the method according to the invention. The method process illustrated in FIG. 1E according to prior art is, however, in accordance with the present invention, performed differently to the known method, which is illustrated in FIG. 2.

At the beginning of the method illustrated in FIGS. 1A to 1F, the structures of the devices 1 are generated on an active system wafer SYS by a number of processes. At the time illustrated in FIG. 1A, the system wafer SYS still has a thickness that offers sufficient mechanical stability. The system wafer SYS includes the processed structures of the devices 1 in the usable surface on its front side.

In the process of the known method illustrated in FIG. 1B, the system wafer SYS is bonded to a carrier work piece via its front side (“bonding”). The carrier work piece may be a passive carrier wafer TW that was previously sorted out as being unsuited for the processing as a system wafer SYS, for instance, due to quality deficiencies. The bonding of the system wafer SYS and the carrier wafer TW to a wafer stack SYS/TW is performed by using a bonding substance 2 that is applied in the edge region of the system wafer SYS or the carrier wafer TW, respectively.

In the embodiment illustrated in the drawing, the bonding of the system wafer SYS and of the carrier wafer TW is completely circumferential, so that the bonding substance 2 forms a continuous circle in the edge region of the wafer stack SYS/TW, as can be seen in FIG. 1F. The glue strip 2 has a breadth of approx. 3 mm and is positioned as close as possible to the edge to keep the usable surface of the system wafer SYS as large as possible. Alternatively, the bonding between the system wafer SYS and the carrier wafer TM may also be performed only in points or in separate zones, so that the circles designated with reference number 2 in FIGS. 1B to 1E may only designate individual points of the bonding substance 2 via which the system wafer SYS is bonded to the carrier wafer TW in the edge region.

In the process of the known processing method illustrated in FIG. 1C, the system wafer SYS is thinned. In so doing, the system wafer SYS is ground from its back until the devices 1 on its front side have the desired thickness. The grinding of the system wafer SYS is thus performed in the direction of the arrow illustrated in FIG. 1C until the region of the system wafer SYS illustrated in dashed lines has been ground. During the process of thinning, the system wafer SYS becomes very fragile due to its small thickness, but is stabilized by the bonding to the carrier wafer TW.

According to the process of the known processing method illustrated in FIG. 1D, the ground back of the system wafer SYS may now be subject to further processes, such as tempering, ion implantation, or metallization. In these processes, the thinned system wafer SYS is mechanically stabilized by the bonded carrier wafer TW. Then, the processing of the structures of the devices 1 generated on the usable surface of the system wafer SYS is finished, and the structures may now be individualized. To this end, the carrier wafer TW has to be separated from the system wafer SYS again so as to enable the access to the devices 1.

FIGS. 1E and 1F illustrate the state of the wafer stack SYS/TW after the carrier wafer TW was again separated from the system wafer SYS in the method according to prior art. To this end, the carrier wafer TW is cut out radially at a distance of approx. 3 to 5 mm from the edge circularly along the dashed cutting line 4 (so-called “decapping line”). The cut-out circular inner portion is removed, and only the edge region in the shape of a ring R with a breadth of 3 to 5 mm which is still strongly bonded to the system wafer via the glue is left from the carrier wafer TW. For further stabilization, the system wafer SYS may additionally be provided with a saw frame 3 that surrounds the thinned system wafer SYS.

During the cutting out of the carrier wafer TW, the system wafer SYS with the devices 1 structured thereon remains unmodified, i.e. the system wafer SYS is not cut during the cutting out of the carrier wafer TW. In the schematic top view on the wafer stack SYS/TW of FIG. 1F, the saw paths can also be seen, which are applied to the system wafer SYS so as to individualize the ready-structured devices 1.

FIG. 2 illustrates a schematic representation of a wafer stack that is processed in accordance with a method according to a preferred embodiment of the present invention, wherein FIG. 2 illustrates a schematic cross-section of the wafer stack. With respect to the proceeding of the method, the state of the wafer stack SYS/TW illustrated in FIG. 2 is comparable to the state of the wafer stack SYS/TW illustrated in FIG. 1E. This means that the method according to the invention first of all starts with the method processes illustrated in FIGS. 1A to 1D. The method process according to prior art illustrated in FIG. 1E is, however, performed differently vis-à-vis prior art in the method according to the invention, and is illustrated in FIG. 2.

In contrast to the known method, the carrier work piece is separated from the system wafer SYS not by cutting out the carrier wafer TW, but the bonding substance or the glue 2, respectively, is heated such that chemical processes in the bonding substance 2 start, which cancel the bonding effect of the glue 2, so that the system wafer SYS may then be detached from the carrier wafer TW.

In one embodiment, the glue 2 is composed on a silicone basis with respect to its chemical composition, such as the commercial silicone glue “Semicosil 987”. If the silicone glue 2 is heated and in so doing subject to an oxygen atmosphere, the silicone converts to silicon oxide or sand, respectively. This way, a granulation of the glue takes place and the glue 2 loses its adhesion.

In order to achieve the temperature of the glue 2 required for the above-described chemical processes, the complete wafer stack SYS/TW of the system wafer SYS may be heated in a furnace. In the embodiment of the present invention illustrated in FIG. 2, the regions of the system wafer SYS bonded via the glue 2 are heated by using laser light L1, and/or the regions of the carrier wafer TW bonded via the glue 2 are heated by using irradiation by laser light L2 so as to heat the glue 2 that is present between the wafers SYS, TW. Additionally or alternatively, the glue 2 may be directly heated by using laser light L3 that is directed into the gap between the system wafer SYS and the carrier wafer TW and thus directly onto the glue 2.

After the wafer stack has cooled down, the system wafer SYS can easily be detached from the carrier wafer TW. If necessary, the wafer stack SYS/TW may be knocked against slightly so as to completely resolve the loose assembly of the granulated bonding substance or glue 2 that is available as sand after the chemical reaction by the heating, and to convey it out of the gap between the system wafer SYS and the carrier wafer TW.

Thus, the method and the device according to the present invention offer the advantages that the wafer stack SYS/TW need no longer be generated by mechanically stressing and dust-prone cutting out of the carrier wafer TW. Due to the inventive heating and oxidizing of the glue 2 and the easy separating of the system wafer SYS from the carrier wafer TW, the system wafer SYS and the structures of the devices 1 processed on its usable surface are subject to a minor mechanical stress and a minor dust exposure.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for processing a wafer comprising:
bonding the system wafer to a carrier work piece over at least a region of the system wafer by using a bonding substance with bonding effect;
performing at least one process on the system wafer; and
canceling the bonding effect of the bonding substance.

2. The method of claim 1, comprising:
separating the system wafer from the carrier workpiece.

3. The method of claim 1, comprising:
canceling the bonding effect of the bonding substance by heating the bonding substance.

4. A method for processing a wafer, wherein a system wafer is subject to a number of process steps so as to structure a number of devices on the system wafer, and wherein the system wafer is bonded to a carrier work piece so as to increase the stability of the system wafer, comprising:
bonding the system wafer to a carrier work piece over at least a particular region of the system wafer by using a bonding substance with bonding effect;
performing one or several intermediate processes for processing the system wafer;
heating the bonding substance, so that the bonding effect of the bonding substance is cancelled; and
separating the system wafer from the carrier work piece.

5. The method of claim 4, comprising performing the heating of the bonding substance by supplying oxygen, so that the bonding substance gets into contact with the oxygen and oxidizes.

6. The method of claim 4, comprising performing the heating of the bonding substance by using a furnace.

7. The method of claim 4, comprising performing the heating of the bonding substance by using heat radiation.

8. The method of claim 4, wherein the heating of the bonding substance by using laser light.

9. The method of claim 4, comprising performing the heating of the bonding substance between the system wafer and the carrier work piece by using a heat radiation source and/or laser light by direct irradiation of the bonding substance from the side into the gap between the system wafer and the carrier work piece.

10. The method of claim 4, comprising performing the heating of the bonding substance by heating of the system wafer and/or the carrier work piece substantially in those regions of the system wafer and/or the carrier work piece via which the system wafer and the carrier work piece are bonded to each other.

11. The method of claim 4, comprising performing the heating of the bonding substance by using a mask that allows for an irradiation by heat radiation or laser light substantially only in those regions of the system wafer and/or the carrier work piece via which the system wafer and/or the carrier work piece are bonded to each other, so that a heating of the system wafer and/or the carrier work piece is substantially only performed in those regions in which bonding substance is present.

12. The method of claim 4, comprising performing the heating of the bonding substance and/or of the bonded regions of the system wafer and/or the carrier work piece by using heat radiation or laser light simultaneously or successively by continuous or step-wise modification of the irradiated faces.

13. The method of claim 4, comprising heating the bonding substance to a temperature in the range between 400° C. to 500° C.

14. The method of claim 4, comprising wherein the bonding substance oxidizes by the effect of heat and oxygen.

15. The method of claim 4, comprising radially bonding the system wafer and the carrier work piece to each other in the edge region of the system wafer.

16. The method of claim 4, comprising bonding the system wafer and the carrier work piece to each other at points.

17. The method of claim 4, comprising bonding the system wafer and the carrier work piece to each other in several zones.

18. The method of claim 4, comprising performing the bonding of the system wafer and the carrier work piece by gluing by using a glue with silicone material.

19. The method of claim 4, comprising wherein the performing of one or several intermediate processes for processing the system wafer comprises the thinning of the system wafer.

20. A system for processing a wafer comprising:
a device configured to structure a number of devices on the system wafer, and wherein the system wafer is bonded to a carrier work piece by using a bonding substance so as to increase the stability of the system wafer; and
a mechanism for heating the bonding substance such that the bonding effect of the bonding substance is cancelled and the system wafer can be detached again from the carrier work piece.

21. The system of claim 20, wherein the mechanism comprises an oxygen supply mechanism configured to supply oxygen during the heating of the bonding substance, so that the bonding substance gets into contact with the oxygen and oxidizes.

22. The system of claim 20, comprising wherein the mechanism is configured to heat the bonding substance by heating the system wafer and/or the carrier work piece substantially in those regions via which the system wafer and the carrier work piece are bonded to each other by the bonding substance.

23. The system of claim 20, wherein the mechanism comprises a furnace for heating the bonding substance.

24. The system of claim 20, wherein the mechanism comprises a heat radiation source that is configured such that the bonding substance can be heated directly or by irradiation of the bonded regions of the system wafer and/or the carrier work piece with laser light.

25. The system of claim 20, wherein the mechanism comprises a laser that is configured such that the bonding substance can be heated directly or by irradiation of the bonded regions of the system wafer and/or the carrier work piece with laser light.

26. The system of claim 20, wherein the mechanism comprises a laser that is configured such that the bonding substance can be heated by direct irradiation with laser light into the gap between the system wafer and the carrier work piece.

27. The system of claim 20, comprising wherein the radiation means, the radiation duration, and/or the radiation performance of the heat radiation source or of the laser is/are controllable.

28. The system of claim 20, comprising wherein the radiation duration of the heat radiation source or of the laser is operable continuously or pulse-wise.

29. The system of claim 20, comprising wherein the laser and/or the heat radiation source is/are configured such that the heating of the bonding substance and/or the bonded regions of the system wafer and/or the carrier work piece is performed by using irradiation by the heat radiation source or the laser simultaneously or successively by continuous or step-wise modification of the irradiated faces.

30. The system of claim 20, wherein the mechanism further comprises a mask that allows for an irradiation by the heat radiation source or the laser substantially only in those regions of the system wafer and/or the carrier work piece via which the system wafer and the carrier work piece are bonded to each other, so that a heating of the system wafer and/or the carrier work piece is substantially only performed in those regions in which bonding substance is present.

31. The system of claim 20, comprising wherein the mechanism is adapted to heat the bonding substance to a temperature in the range between 400° C. and 500° C.
